(19) United States
(12) Patent Application Publication
(10) Pub. No.: US 2024/0343886 A1
(43) Pub. Date: Oct. 17, 2024

(54) STRETCHING ELECTRODE AND STRETCHING MODULE INCLUDING THE SAME

(71) Applicant: T&L Health Care Corp., Yongin-si (KR)

(72) Inventors: Do Gi PYUN, Suwon-si (KR); In Me KIM, Seongnam-si (KR)

(21) Appl. No.: 18/418,625

(22) Filed: Jan. 22, 2024

(30) Foreign Application Priority Data
Apr. 17, 2023 (KR) 10-2023-0050178

(51) Int. Cl. C08K 3/08; C08J 5/18; C08L 75/04; C09D 5/24

(52) U.S. Cl. CPC C08K 3/08; C08J 5/18; C08L 75/04; C09D 5/24; C08K 2003/0806; C08K 2201/011

(57) ABSTRACT

The present disclosure relates to a stretching electrode in which silver nanowires AgNHs, silver microparticles AgMPs, and silver nanoparticles AgNPs are included in a heat-resistant thermosetting resin, the silver nanowires AgNWs have a positive charge (+) and the silver nanoparticles AgNPs have a negative charge (−), and the heat-resistant thermosetting resin is a polyurethane resin.

### CROSS-REFERENCE TO RELATED APPLICATION

This application claims the benefit of Korean Application No. 10-2023-0050178 filed on Apr. 17, 2023 with the Korean Intellectual Property Office, the disclosure of which is incorporated herein by reference.

### BACKGROUND OF THE INVENTION

### 1. Field of the Invention

The present disclosure relates to a stretching electrode and a stretching module including the same, and more particularly, to a stretching electrode which is configured by silver nanowires AgNWs and silver particles AgMPs or AgNPs to have excellent conductivity.

### 2. Description of the Related Art

In recent studies are being conducted on attachable devices which directly attach display devices or biological devices, such as smart skin devices, soft robots, and biomedical devices to objects, skins, or clothing. Attachable devices require stretchability to flexibly respond to a shape of the object or a motion of a living body and restore it to its original state.

Today, research is actively developed on stretchable electronic devices in which electrodes are formed on flexible substrates (for example, FPCB), beyond conductive devices in which electrodes are formed on rigid substrates. The stretchable electronic devices are next-generation electronic devices which are manufactured on substrates which are freely stretched in response to an external stress and maintain the device's electrical/physical characteristics even when mechanical deformation or external force is applied. Such a stretchable electronic device is applicable to a flexible apparatus, a wearable apparatus, or the like and may be also utilized as a sensor, an electrode, or the like attached into a display or a human body.

In the meantime, in recent years, technologies about a method for forming an electrode on a stretching substrate, that is, a stretchable substrate (stretchable PCB, SPCB) are actively developing beyond forming an electrode on a flexible substrate, that is, a flexible printed circuit board FPCB.

When an electrode is formed on a stretching film, the usability can be vaster than forming an electrode on a flexible film. For example, as the stretching substrate is stretchable in various directions, a sensor is implemented on the stretching substrate and a module is placed in a separate location so that the module and the sensor do not need to be integrally provided. Accordingly, the sensor may be attached in various locations so that the wearing comfort is increased to improve a measurement accuracy of the sensor.

To this end, the development of the stretching electrode having an excellent resistance change rate compared to the conductivity and the stretchability is required.

### SUMMARY OF THE INVENTION

An object to be achieved by the present disclosure is to solve the above-described problem and provide a stretching electrode in which silver nanowires and silver microparticles are mixed in urethane resin to ensure conductivity and flexibility.

Further, another object of the present disclosure is to provide a stretching film which has an adhesiveness with the stretching electrode and elasticity by forming a curved film by a surface treatment.

In order to solve the above-described problem, the present disclosure provides a stretching electrode in which silver nanowires AgNWs, silver microparticles AgMPs, and silver nanoparticles AgNPs are included in a heat-resistant thermosetting resin.

Further, according to the present disclosure, in the stretching electrode, the silver nanowires AgNWs have a positive charge (+) and the silver nanoparticles AgNPs have a negative charge (−).

Further, according to the present disclosure, in the stretching electrode, the heat-resistant thermosetting resin is polyurethane resin.

The present disclosure provides a stretching module in which a stretching electrode is laminated on one surface of a stretching film.

According to the present disclosure, in the stretching module, one surface of the stretching film is processed with an unevenness structure.

According to the present disclosure, in the stretching module, a support is laminated on a rear surface of the stretching film.

According to the present disclosure, in the stretching module, a conductive bond is laminated on a rear surface of the stretching electrode.

According to the present disclosure, in the stretching module, the conductive bond connects the stretching electrode and an electronic component.

According to the present disclosure, in the stretching module, a sealed stretching material is added on four outer edges of the stretching electrode, the conductive bond, and the electronic component to fix the electronic component.

According to the present disclosure, the stretching electrode in which silver nanowires and silver microparticles are mixed in urethane resin provides conductivity and flexibility.

Further, according to the present disclosure, in the stretching film, the film is formed to be curved by the surface treatment to ensure the adhesiveness to the stretching electrode and the elasticity.

### BRIEF DESCRIPTION OF THE DRAWINGS

FIG. 1 is a view for explaining a composition of a stretching electrode of the present disclosure.

FIG. 2 is a conceptual view of a molecular structure of a stretching electrode of the present disclosure.

FIG. 3 is a conceptual view of a stretching film and a support of the present disclosure.

FIG. 4 is a cross-sectional view and a top view of a stretching module of the present disclosure.

FIGS. 5 and 6 are graphs illustrating resistance measurement values according to a stretching rate according to Exemplary Embodiment of the present disclosure and Comparative Embodiment.

### DETAILED DESCRIPTION OF THE PREFERRED EMBODIMENT

Hereinafter, exemplary embodiments of the present disclosure will be described in more detail. First, in describing the present disclosure, a detailed description of publicly known functions or configurations incorporated herein will be omitted so as not to make the subject matter of the present disclosure unclear.

The terms “about or approximately” or “substantially” indicating a degree used throughout the specification are used as a numerical value or a meaning close to the numerical value when a unique manufacturing and material tolerance is proposed to the mentioned meaning and also used to prevent unscrupulous infringers from wrongfully using the disclosure in which precise or absolute numerical values are mentioned for better understanding of the present disclosure.

The present disclosure relates to a stretching electrode in which silver nanowires (AgNWs), silver microparticles (AgMPs), and silver nanoparticles (AgNPs) are included in a heat-resistant thermosetting resin.

The silver nanowires AgNWs have a diameter of 3.5 μm and a length of 260±0.7 μm, and a diameter of the silver nanoparticles AgNPs is appropriately 3.7±0.7 μm, and a diameter of the silver microparticles AgMPs is appropriately of 16.4±1.0 μm, but are not limited thereto.

The core of the stretching technology lies in the stretching electrode and not only the simple elasticity is important, but also the ratio of the resistance value to the stretching rate needs to be low. In the present disclosure, in order to minimize the power consumption and the data distortion, an initial resistance value needs to be 2Ω or lower based on a pattern width of 0.8 T and a length of 100 mm and especially, the important thing is that component mounting (SMD) should be possible to be applicable as an electronic component.

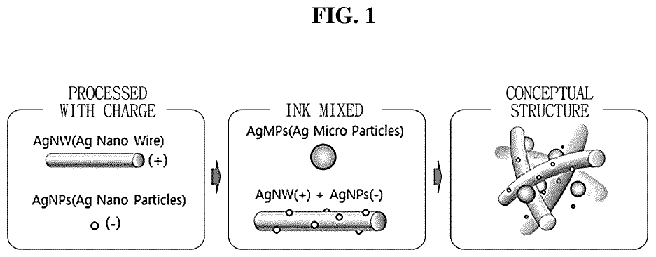

FIG. 1 is a view for explaining a composition of a stretching electrode of the present disclosure. The stretching electrode has AgNPs (Ag nanoparticles) as a main component and AgMPs, AgNPs, AgNWs, and like may be mixed therewith to achieve the conductivity and the stretchability.

Further, in order to solidify the particles, a small amount of conductive or non-conductive stretching materials is included and a curing agent may be included for solidification.

Specifically, the stretching electrode resin which is formed and mixed with the above-mentioned material has a viscosity which enables screen and 3D printing and is applied with one or more layers to configure the stretching electrode.

After precisely printing the stretching electrode on the stretching substrate, a curing process may be performed.

As a thermosetting resin, any one of phenol resin, urea resin, unsaturated polyester resin, polyurethane, alkyd resin, melamine resin, epoxy resin, and silicon resin may be used and the polyurethane resin is desirable.

The sliver microparticles AgMPs improve the conductivity and maintain the adhesiveness between the stretching electrode and the electronic component. However, there is a disadvantage of causing cracks during the stretching so that in order to compensate for this, AgNPs(−) and AgNW(+) which are processed with charge are mixed.

As the charge processing method, three methods may be mainly applicable.

The first method is a chemical method that silver nanoparticles AgNPs are exposed to a chemical solution having negative ions so that negative ions are present on surfaces of the silver nanoparticles AgNPs.

The second method is a plasma method that silver nanoparticles AgNPs are exposed to plasma having negative ions so that the plasma which is gas with high energy supplies a sufficient amount of energy to surfaces of the particles to charge negative ions on the surfaces of the particles.

The third method is an electrolyte solution method that silver nanoparticles AgNPs are exposed to an electrolyte solution having negative ions to form an electric field between the silver nanoparticles AgNPs and the electrolyte solution to charge negative ions from the electrolyte solution on the surfaces of the silver nanoparticles AgNPs.

Likewise, a method of charging the silver nanowires AgNWs with positive ions is also used for the method.

The silver nanoparticles AgNPs serve to fill voids between the silver microparticles AgMPs and the silver nanowires AgNWs when the stretching electrode is stretched and the silver nanoparticles AgNPs are attached to the silver nanowires AgNWs to increase the probability of surface contact with the silver microparticles AgMPs.

Further, the silver nanoparticles AgNPs serve to maintain conductivity between the silver microparticles AgMPs.

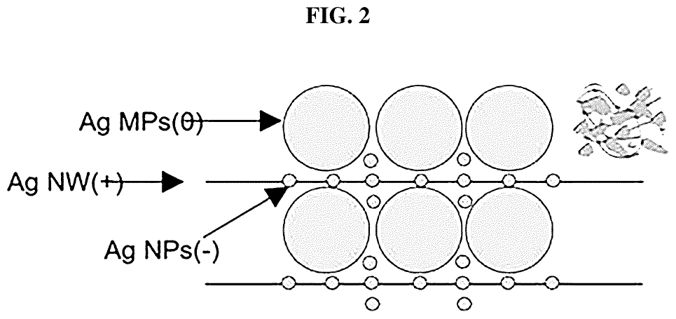

FIG. 2 is a conceptual view of a molecular structure of a stretching electrode of the present disclosure.

With regard to the configuration and mixture of the stretching electrode resin, the silver nanoparticles AgNPs are processed with negative (−) charges and the silver nanowires AgNWs are processed with positive (+) charges before being mixed with the resin. Therefore, at the time of being mixed with the resin, AgNPs(−) are adhered onto AgNW(+) to supplement the voids between surrounding AgMPs and minute cracks which may be generated during the stretching and maintain the conductivity. It is similar to the structure in which minute conductive particles are stuck in a scrubber. The mixture of the stretching electrode and the resin is as represented in the following Table 1.

TABLE 1

| | Material charge | Mixture ratio |
|---|---|---|
| Material | processing | (Weight %) |
| AgNPs (Ag nanoparticles) | − | 8 to 18 |
| AgMPs (Ag microparticles) | 0 | 40 to 60 |
| AgNWs (Ag nanowires) | + | 4 to 14 |
| Heat-resistant urethane | 0 | 13 to 23 |
| Curing solvent (Gamma- | 0 | 5 to 15 |
| butyrolactone) | | |

Next, the stretching electrode is laminated on one surface of the stretching film. The laminated form is called a stretching module and a form in which electronic components are mounted on the stretching substrate to be fixed is also included in the stretching module.

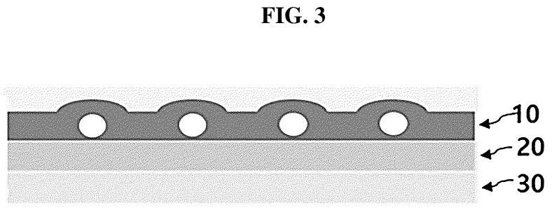

FIG. 3 is a conceptual view of a stretching film and a support of the present disclosure.

A stretching film of the stretching module is configured by any one of polyurethane, elastomer, silicon (polyvinyl siloxane), polydimethylsiloxane, and octamethylcylotetrasiloxane.

Additionally, the film is formed to be curved by means of the surface treatment of the stretching film to provide the adhesiveness with the stretching electrode and the elasticity.

The surface treatment is performed by directly processing one surface of the stretching film or by an additional surface-forming method.

For example, various micro- and nano-level surface treatments, such as gravure coating with micropatterns, surface formations through microparticle raw material, corrosion treatment, corona treatment, and matt treatment are applied to the stretching film to provide the adhesiveness with the stretching electrode and the elasticity.

Further, a separate microparticle-mixed insulating paint which improves the adhesiveness of the stretching electrode and the stretching film and forms a curved surface with an arbitrary shape by mixing the microparticles is applied on a top of the stretching film to improve the stretchability and resilience of the film.

Next, a support may be laminated on a rear surface of the stretching film. As the support, heat-resistant polyester resin (PET) is desirable and the support may block the shrinkage deformation due to the degradation of the stretching module by attaching (laminating) the heat-resistant stretching film on the bottom to prevent the shrinkage or deformation during the curing process of the stretching film.

Further, a conductive bond is laminated on the rear surface of the stretching electrode and the conductive bond serves to connect the stretching electrode and the electronic component.

A material configuration of the conductive bond is similar to the stretching electrode. However, as represented in Table 2, copper powder CuMPs or zinc powder ZnMPs may be added to increase the conductivity and the adhesiveness with the electronic component, and the epoxy resin is added to increase the viscosity and is mixed to facilitate the MIR curing. At this time, the viscosity is desirably 10000 to 12000 Pa·s.

TABLE 2

| | Material charge | Mixture ratio |
|---|---|---|
| Material | processing | (weight %) |
| AgMPs | 0 | 30 to 70 |
| (Ag microparticles) | | |
| CuMPs | 0 | 0 to 30 |
| (Cu microparticles) | | |
| ZnMPs | 0 | 0 to 30 |
| (Zn microparticles) | | |
| Epoxy resin | 0 | 10 to 30 |
| Curing agent | 0 | 5 to 15 |

Here, in order to fix the electronic component located on the conductive bond, sealed stretching materials may be added on four outer edges of the stretching electrode, the conductive bond, and the electronic component.

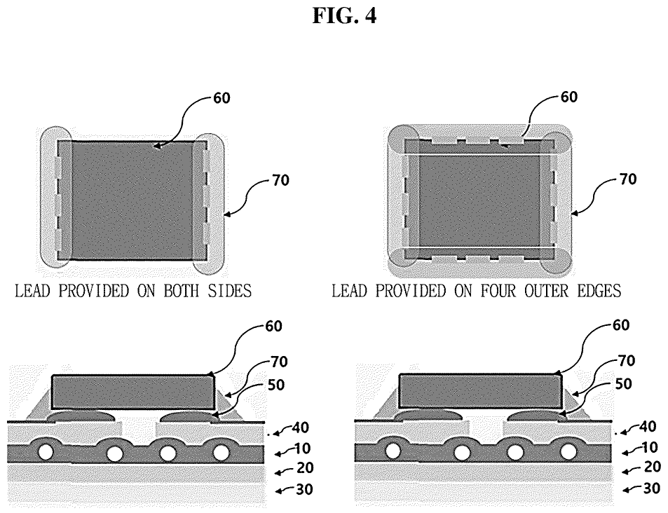

FIG. 4 is a cross-sectional view and a top view of a stretching module of the present disclosure. The stretching material may be sealed in only a part of outer edges of the electronic components or may be sealed in all four surfaces.

Even after attaching the electronic component on the conductive bond in the stretching module, the electronic component may be detached due to the external shock applied to the stretching module so that the substrate adhesiveness of the electronic components needs to be maintained at least 1 Kg·a. With regard to this, a lead of the electronic component and a solder part of the stretching electrode are sealed with stretching materials, such as urethane or epoxy having a hardness of 80, silicon (polyvinyl siloxane), polydimethylsiloxane, or octamethylcylotetrasiloxane and then cured with UV to be fixed.

The stretching substrate is configured with the molecular structure of the stretching electrode and the structure of the stretching film and the stretching module may be configured by mounting the electronic component and such a conceptual technology may configure an attachable or wearable electronic device, such as a health care or wearable device.

The features and other advantages of the present description as described above will become more apparent from the exemplary embodiments described below, and the exemplary embodiments below are only described for illustrative purposes and should not be construed as limiting or restricting the scope of protection of the present disclosure.

### EXEMPLARY EMBODIMENT

9% by weight of positive charge (+)-processed silver nanowires AgNWs, 13% by weight of negative charge (−)-processed silver nanoparticles AgNPs, 50% by weight of silver microparticles AgMPs, 18% by weight of heat-resistant urethane resin, and 10% by weight of curing solvent (Gamma-butyrolactone) were mixed and then printed with a thickness of 0.01 mm on a PU film.

### Comparative Embodiment

22% by weight of silver nanowires AgNWs, 50% by weight of silver microparticles AgMPs, 18% by weight of heat-resistant urethane resin, and 10% by weight of curing solvent (Gamma-butyrolactone) were mixed and then printed with a thickness of 0.01 mm on a PU film. The other conditions are the same as Example.

TABLE 3

| | Measurement of resistance | | | | | |
|---|---|---|---|---|---|---|
| | according to stretching rate(Ω) | | | | | |
| Sample | Initial | 10%- | 20%- | 30%- | 40%- | Occurrence |
| No. | resistance | Stretched | Stretched | Stretched | Stretched | of Crack |
| 1 | 0.9 | 1.5 | 2.6 | 4.2 | 6.4 | None |
| 2 | 1.0 | 1.6 | 2.7 | 4.4 | 6.8 | None |
| 3 | 0.9 | 1.6 | 2.7 | 4.3 | 6.7 | None |
| 4 | 1.0 | 1.5 | 2.6 | 4.0 | 6.1 | None |
| 5 | 0.9 | 1.5 | 2.5 | 4.1 | 6.2 | None |
| 6 | 1.0 | 1.5 | 2.4 | 4.2 | 6.3 | None |

Table 3 is a result obtained by measuring a resistance according to a stretching rate from five samples of Exemplary Embodiment.

TABLE 4

| | Measurement of resistance | | | | | |
|---|---|---|---|---|---|---|
| | according to stretching rate(Ω) | | | | | |
| Sample | Initial | 10%- | 20%- | 30%- | 40%- | Occurrence |
| No. | resistance | Stretched | Stretched | Stretched | Stretched | of Crack |
| 1 | 0.5 | 1.3 | 2.8 | 5.3 | 9.0 | 40% crack |
| | | | | | | (externally) |
| 2 | 0.6 | 1.3 | 3.0 | 6.0 | 11.9 | 30% crack |
| | | | | | | (externally) |
| 3 | 0.5 | 1.4 | 3.5 | 7.0 | Crack | 40% crack |
| | | | | | | (externally) |
| 4 | 0.5 | 1.3 | 3.0 | 5.6 | 9.2 | 30% crack |
| | | | | | | (externally) |
| 5 | 0.5 | 1.4 | 3.4 | 6.6 | 11.1 | 40% crack |
| | | | | | | (externally) |
| 6 | 0.5 | 1.2 | 3.0 | 5.7 | 9.3 | 30% crack |
| | | | | | | (externally) |

Table 4 is a result obtained by measuring a resistance according to a stretching rate from five samples of Comparative Embodiment.

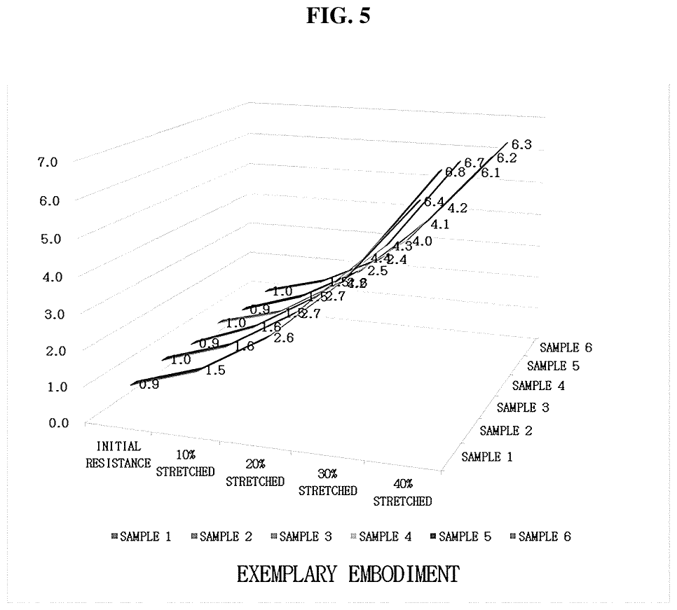

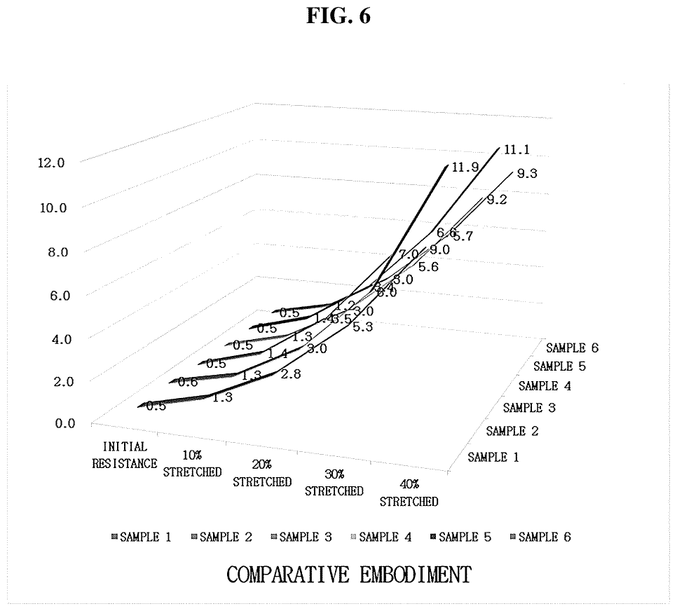

FIGS. 5 and 6 are graphs illustrating resistance measurement values according to a stretching rate according to Exemplary Embodiment of the present disclosure and Comparative Embodiment. Referring to Tables 3 and 4 and FIGS. 5 and 6, it is understood that Exemplary Embodiment of the present disclosure has a resistance change value according to the increase of the stretching rate which is smaller than Comparative Embodiment, and does not have cracks.

The foregoing present disclosure is not limited to the foregoing exemplary embodiments and the accompanying drawings. It will be apparent to those skilled in the art that various modifications and changes may be made without departing from the scope and spirit of the disclosure.

What is claimed is:

1. A stretching electrode in which silver nanowires AgNWs, silver microparticles AgMPs, and silver nanoparticles AgNPs are included in a heat-resistant thermosetting resin.

2. The stretching electrode according to claim 1, wherein the silver nanowires AgNWs have a positive charge (+) and the silver nanoparticles AgNPs have a negative charge (−).

3. The stretching electrode according to claim 1, wherein the heat-resistant thermosetting resin is a polyurethane resin.

4. A stretching module in which the stretching electrode according to claim 1 is laminated on one surface of a stretching film.

5. A stretching module in which the stretching electrode according to claim 2 is laminated on one surface of a stretching film.

6. A stretching module in which the stretching electrode according to claim 3 is laminated on one surface of a stretching film.

7. The stretching module according to claim 4, wherein the one surface of the stretching film is processed to have an unevenness structure.

8. The stretching module according to claim 4, wherein a support is laminated on a rear surface of the stretching film.

9. The stretching module according to claim 4, wherein a conductive bond is laminated on a rear surface of the stretching electrode.

10. The stretching module according to claim 9, wherein the conductive bond connects the stretching electrode and an electronic component.

11. The stretching module according to claim 10, wherein a sealed stretching material is added on four outer edges of the stretching electrode, the conductive bond, and the electronic component to fix the electronic component.
